(19) United States
(12) Patent Application Publication
(10) Pub. No.: US 2007/0163714 A1
(43) Pub. Date: Jul. 19, 2007

(54) Etch chamber

(76) Inventors: Hong Jin Kim, Singapore (SG); Jose Angeles Talban, Philippines (PH); Abdul Rahim Abdul Malik, Singapore (SG); Ronnie San Diego David, Singapore (SG)

Correspondence Address: GOODWIN PROCTER L.L.P, 599 LEXINGTON AVE., NEW YORK, NY, 10022, US

(21) Appl. No.: 11/334,258

(22) Filed: Jan. 18, 2006

(51) Int. Cl. C03C 25/68; H01L 21/306; C23F 1/00

(52) U.S. Cl. 156/345.3; 216/58; 156/345.29

(57) ABSTRACT

An etch chamber and a method of reducing back flow of particles in an etch chamber having a valve connected thereto. The etch chamber comprises a valve connected to the etch chamber; and a liner a liner disposed to cover an internal gap between a flange portion of the valve and a flange portion of the etch chamber.

### FIELD OF INVENTION

The present invention relates broadly to an etch chamber and to a method of reducing back flow of particles in an etch chamber having a valve connected thereto.

### BACKGROUND OF THE INVENTION

Etch chambers typically comprise a pump connected to the etch chamber via a gate valve. There exist internal gaps or recesses in the etch chamber walls, for example, at the connection between the gate valve and the etch chamber. It has been recognised by the inventors that there is a tendency for polymer or particles to build up inside the gaps. The polymer or particles that accumulate in the gaps may be dislodged and flow back into the etch chamber when the gate valve is opened and closed, as a result of the associated pressure changes. The flow of polymer or particles back into the etch chamber reduces the performance of the etch chamber.

Some conventional etch chambers comprise chamber liners to protect the chamber walls from erosion and wear due to the plasma etching. These chamber liners will need to be replaced when they are worn out. Particles from the plasma etching can contribute to the accumulation of particles in the above mentioned gaps. The chamber liners are typically disposed in the main body of the etch chamber and do not extend into interconnecting portions of the etch chamber such as into flange or port portions of the etch chamber.

### SUMMARY OF THE INVENTION

In accordance with a first aspect of the present invention there is provided an etch chamber comprising a valve connected to the etch chamber; and a liner disposed to cover an internal gap between a flange portion of the valve and a flange portion of the etch chamber.

The etch chamber may further comprise an O-ring disposed between the flange portions of the valve and the etch chamber respectively for sealing engagement of the flange portions of the valve and the etch chamber respectively.

The liner may be generally cylindrical in shape.

The liner may comprise a stepped profile.

### The liner may be shaped to fit over the gap in a manner such that play between the liner and adjacent wall portions is substantially minimised.

The liner may comprise a curved rim at an end of the liner facing away from the valve.

The valve may comprise a gate valve.

The valve may comprise a throttling gate valve.

A pump may be connected to the valve at a side opposite to the etch chamber.

The pump may comprise a turbo pump.

The liner may be made from anodised metal.

In accordance with a second aspect of the present invention there is provided a method of reducing back flow of particles in an etch chamber having a valve connected thereto, the method comprising the step of providing a liner to cover an internal gap between a flange portion of the valve and a flange portion of the etch chamber.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic cross-sectional view of part of an etch chamber according to an embodiment;

FIG. 2 is a schematic side view of a liner according to the embodiment in FIG. 1; and

FIGS. 3(a) and (b) are photographs showing internal views of an etch chamber without and with a liner inserted respectively, according to another embodiment.

### DETAILED DESCRIPTION OF THE INVENTION

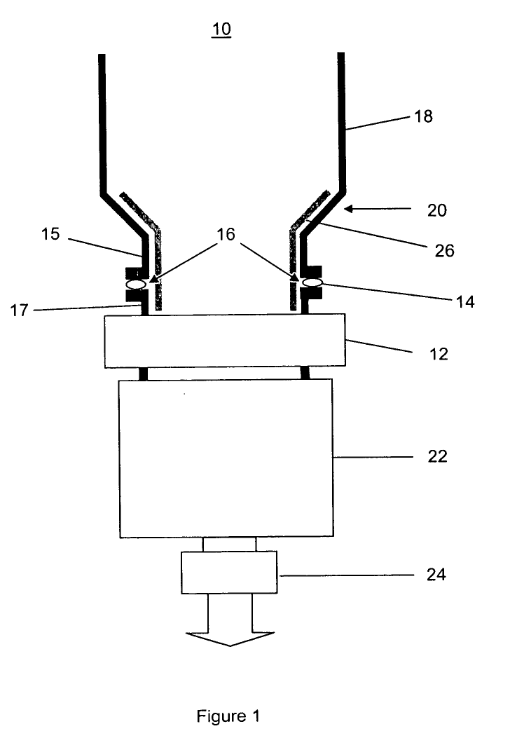

A schematic cross-sectional view of part of an AMAT DPS etch chamber 10, according to a first embodiment, is shown in FIG. 1. The etch chamber 10 comprises a gate valve 12 connected to the etch chamber 10 and an O-ring 14 disposed between the etch chamber 10 and the gate valve 12.

An internal gap 16 exists between a flange portion 17 of the gate valve 12 and a flange portion 15 of the etch chamber 10, with the O-ring 14 typically not filing the gap 16 in a manner that is flush with the adjoining inner wall portions of the etch chamber 10 and the gate valve 12.

The etch chamber 10 is connected to the gate valve 12 via the flange portions 15, 17 of the etch chamber 10 and the gate valve 12 respectively. As will be appreciated by a person skilled in the art, the flange portions 15, 17 are connected to each other utilising bolts and nuts (not shown), with the O-ring 14 disposed therebetween for sealing engagement of the flange portions 15 and 17.

A turbo pump 22 is connected to the gate valve 12 on a side opposite the etch chamber 10. The turbo pump 22 and the gate valve 12 comprise flange portions 19, 21 respectively, which again are sealingly engaged utilising nuts and bolts (not shown) and a further O-ring (not shown). The turbo pump 22 is in turn connected to a dry pump 24, forming a staged high-vacuum facility for the etch chamber 10.

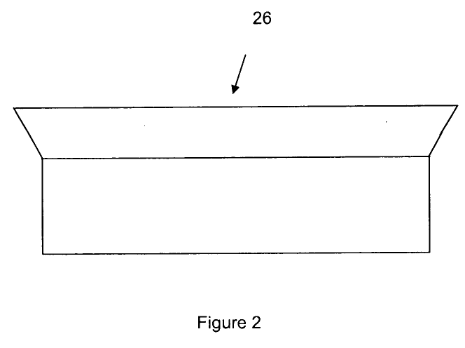

A liner 26 is disposed within the etch chamber 10 such as to cover the gap 16. The liner 26 is generally cylindrical in shape, as shown in FIG. 2. Returning to FIG. 1, the liner 26 is stepped to correspond and extend along a tapered profile 20 of the flange portion 15 and further extends over the flange portion 17 of the gate valve 12, thereby covering the gap 16. The liner 26 is shaped to fit over the gap 16 in a manner such that play between the liner 26 and the adjacent wall portions is substantially minimised, according to manufacturing tolerances. The liner 26 is made from anodised metal. The anodisation thickness of the liner 26 is about 40±5 μm.

During operation of the etch chamber 10 without the liner 26, particles such as polymers were found to typically build up in the gap 16. When the gate valve 12 is opened and closed, for example, during automatic flow controller (AFC) flow visualization or during leak rate checks, the particles accumulated in the gap 16 are dislodged as a result of the associated pressure changes near the gate valve 12, and can flow back into the etch chamber 10, thereby reducing the performance of the etch chamber 10.

By covering the gap 16 with the liner 26, build up of particles in the gap 16 can advantageously be eliminated, and thus the flow of particles back into the etch chamber 10 is greatly minimised, if not eliminated. This results in improved performance of the etch chamber 10.

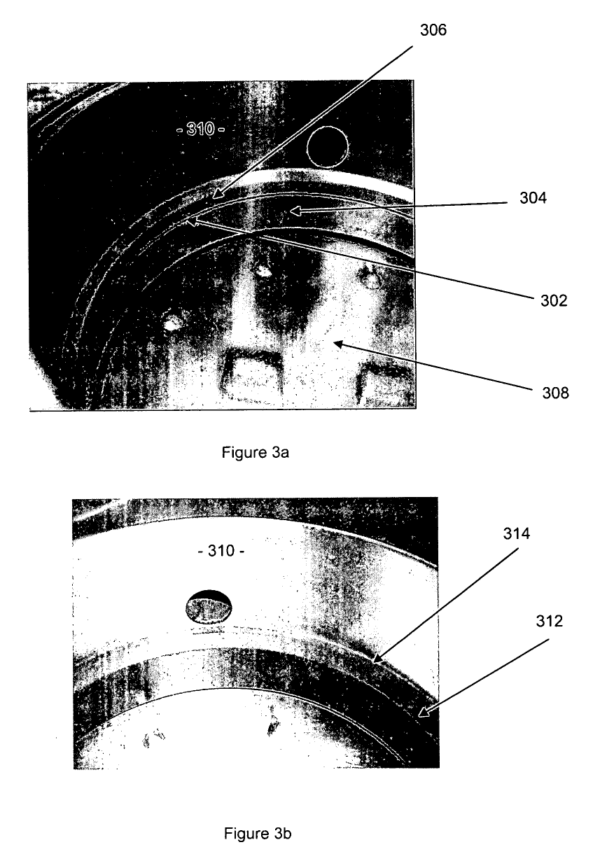

FIGS. 3(a) and (b) show photographs of an internal view of an etch chamber 300 without and with a liner inserted respectively, in a second embodiment. In FIG. 3(a), the gap 302 between a flange portion 304 of the gate valve 308 and a flange portion 306 of the etch chamber 300 is visible. In this embodiment, the flange portion 306 forms part of a port portion 310 of the etch chamber 300.

As shown in FIG. 3(b), the inserted liner 312 covers the gap 302 (FIG. 3(a)), to advantageously eliminate build up of particles in the gap 302 (FIG. 3(a)), to minimize, and possibly eliminate, the flow of particles back into the etch chamber 300. In this example embodiment, the liner 312 has a curved rim 314, to further minimize or eliminate build up of particles at the rim 314 of the liner 312.

It will be appreciated that the etch chamber may be connected to other types of valves such as a throttling gate valve. In a third embodiment where a throttling gate valve is connected to the etch chamber, the problem of particles flowing back into the etch chamber without using a liner to cover the gap between the etch chamber and the valve was found to be severe as the throttling gate valve is opened and closed continuously to maintain the required pressure in the etch chamber. With a liner having a profile corresponding with an internal profile of a flange portion of the etch chamber and a flange portion of the valve to cover the gap, build up of particles in the gap can advantageously be eliminated. Thus the flow of particles back into the etch chamber can be greatly minimised, and possibly eliminated, resulting in improved performance of the etch chamber.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, the shape and profile of the liner may be different from that described above. Generally, in different embodiments the profile of the liner should correspond with an internal profile of the flange portion of the etch chamber and the flange portion of the valve, such that the liner is able to fit within the etch chamber and over the internal gap between the flange portion of the etch chamber and the flange portion of the valve.

Furthermore, it will be appreciated that the liner for covering the gap between the etch chamber and valve may be formed integrally with, or used together with, a liner used to protect the chamber walls from erosion and wear due to the plasma etching.

1. An etch chamber comprising:
a valve connected to the etch chamber; and
a liner disposed to cover an internal gap between a flange portion of the valve and a flange portion of the etch chamber.

2. The etch chamber as claimed in claim 1, further comprising an O-ring disposed between the flange portions of the valve and the etch chamber respectively for sealing engagement of the flange portions of the valve and the etch chamber respectively.

3. The etch chamber as claimed in claim 1, wherein the liner is generally cylindrical in shape.

4. The etch chamber as claimed in claim 3, wherein the liner comprises a stepped profile.

5. The etch chamber as claimed in claim 1, wherein the liner is shaped to fit over the gap in a manner such that play between the liner and adjacent wall portions is substantially minimised.

6. The etch chamber as claimed in claim 1, wherein the liner comprises a curved rim at an end of the liner facing away from the valve.

7. The etch chamber as claimed in claim 1, wherein the valve comprises a gate valve.

8. The etch chamber as claimed in claim 1, wherein the valve comprises a throttling gate valve.

9. The etch chamber as claimed in claim 1, wherein a pump is connected to the valve at a side opposite to the etch chamber.

10. The etch chamber as claimed in claim 9, wherein the pump comprises a turbo pump.

11. The etch chamber as claimed in claim 1, wherein the liner is made from anodised metal.

12. The etch chamber as claimed in claim 2, wherein the liner is generally cylindrical in shape.

13. The etch chamber as claimed in claim 2, wherein the liner is shaped to fit over the gap in a manner such that play between the liner and adjacent wall portions is substantially minimised.

14. The etch chamber as claimed in claim 2, wherein the liner comprises a curved rim at an end of the liner facing away from the valve.

15. The etch chamber as claimed in claim 2, wherein the valve comprises a gate valve.

16. The etch chamber as claimed in claim 2, wherein the valve comprises a throttling gate valve.

17. The etch chamber as claimed in claim 2, wherein a pump is connected to the valve at a side opposite to the etch chamber.

18. The etch chamber as claimed in claim 2, wherein the liner is made from anodised metal.

19. A method of reducing back flow of particles in an etch chamber having a valve connected thereto, the method comprising the step of providing a liner to cover an internal gap between a flange portion of the valve and a flange portion of the etch chamber.
